(19) United States
(12) Patent Application Publication
(10) Pub. No.: US 2008/0007995 A1
(43) Pub. Date: Jan. 10, 2008

(54) Memory cell having a switching active material, and corresponding memory device

(76) Inventor: Ulrike Gruening-von Schwerin, Munchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/483,500

(22) Filed: Jul. 10, 2006

(51) Int. Cl. H01L 29/02; G11C 11/00; H01L 47/00

(52) U.S. Cl. 365/163; 365/158; 257/2

(57) ABSTRACT

A memory device having at least one resistively switching memory cell is disclosed. In one embodiment, the memory cell includes a volume of switching active material and a pair of electrodes being galvanically coupled to the volume of switching active material, wherein the pair of electrodes is adapted to send a current through the volume of switching active material, and at least one gate electrode adapted to cause an electric field penetrating the volume of switching active material. Another embodiment of the invention discloses a method for driving the memory device and a method for producing the same.

### BACKGROUND

The invention relates to a memory cell, in particular a memory cell having a switching active material, and a corresponding memory device.

Conventional memory devices can be grouped according to their principles to store data.

For example in the case of SRAM (SRAM=Static Random Access Memory), the individual memory cells consist of few, for instance of 6, transistors, and in the case of DRAMs (DRAM=Dynamic Random Access Memory) usually only of one single, correspondingly controlled capacitive element, e.g., a selection transistor coupled to a capacitor, wherein one bit can be stored as charge.

DRAMs as well as SRAMs are volatile memories which loose their data at least when the supply voltage is switched off.

In contrast to these memory devices non-volatile memory devices (NVMs), such as EPROMs, EEPROMs or flash memories, keep the stored data in a memory cell even when the supply voltage is switched off.

Recently so called “resistive” or “resistively switching” memory devices have become known, e.g., Phase Change (PC) or Conducting Bridge (CB) memories, which belong to the group of non-volatile memory devices.

In a “resistive” or “resistively switching” memory cell, an “active” or “switching active” material, which usually is positioned between two suitable electrodes, i.e. an anode and a cathode, can be switched between a conductive and a less conductive state by an appropriate switching process. The conductive state can be assigned a logic one and the less conductive state can be assigned a logic zero, or vice versa, which may, for instance, correspond to the logic arrangement of a bit.

For PC memories (PCRAMs), for instance, an appropriate chalcogenide compound, for example Ge—Sb—Te (GST) or an In—Sb—Te compound, may be used as a “switching active” material that is positioned between two corresponding electrodes. This “switching active”, e.g., the chalcogenide material, can be switched between an amorphous and a crystalline state, wherein the amorphous state is the relatively weakly conducting state, which accordingly can be assigned a logic zero, and the crystalline state, i.e. a relatively strongly conductive state, accordingly can be assigned a logic one. In the following this material will be referred to as the switching active material.

To achieve a change from the amorphous, i.e. a relatively weakly conductive state of the switching active material, to a crystalline, i.e. a relatively strongly conductive state, the material has to be heated. For this purpose a heating current pulse is sent through material, which heats the switching active material beyond its crystallization temperature, thus lowering its resistance. In this way the value of a memory cell can be set to a first logic state. Vice versa, the switching material can be heated by applying a relatively high current to the cell which causes the switching active material to melt and by subsequently “quench cooling” the material can be forced into an amorphous, i.e. relatively weakly conductive state, which may be assigned a second logic state, that is to reset the first logic state.

In contrast to phase change memories conducting bridge (CB) memory devices make use of solid state ionic devices being composed of metal doped glasses, generally referred to as solid electrolytes. CB memory cells are composed of a thin film of silver (Ag) or other metal doped chalcogenide or oxide glass, which is sandwiched between electrodes, namely a silver anode and an inert cathode. If voltage is supplied to the electrodes the resulting electrical field effects a current of electrons from the cathode, which reduces an equivalent number of Ag-ions, which have been injected from the anode, thus forming a metal-rich electro deposit in the electrolyte. The magnitude and duration of the current of ions determines the amount of Ag deposited in the electrolyte and hence influences the conductivity of the pathway. By applying a bias voltage with opposite polarity a reverse current flow is effected until the previously injected Ag has been oxidized and deposited back to the electrode which supplied the metal, thus increasing the resistivity again until the high value of the solid electrolyte is reached and thus reversing the formation process. The electro deposit is electrically stable and neutral and the benefits are low voltage operation, high OFF/ON ratios and a considerable scaling potential. This concept is known for example from R. Symanczyk et al. “Electrical Characterization of Solid State Ionic Memory Elements”, Proceedings of the Non-Volatile Memory Technology Symposium 2003, San Diego, USA, 2003, pp 17-1.

Resistance switching has also been reported for binary TMO (transition metal oxides) such as NiOx, NbOx TiOx, HfOx, ZrOx, using a MIN (metal-insulator-metal) stack, e.g., I. G. Baek et al. “Highly Scalable Non-volatile Resistive Memory using Simple Binary Oxide Driven by Asymmetric Unipolar Voltage Pulses, IEDM 2004 and for perovskite oxides, i.e. W. W. Zhuang, “Novell Colossal Magnetoresistive Thin Film Nonvolatile Resistance Random Access Memory (RRAM),” Proceedings of the IEDM 2002.

Common to the described memory concepts for changing the electrical resistivity, that is for writing and erasing a logical state, a structural change takes place in the employed switching active material, whereby high current densities and voltages are applied.

One problem when designing a cost competitive, small sized memory device is that material interfaces are prone to degradation and reliability failures due to temperature stresses, current stresses, material reconfiguration, voiding, delamination, pinning of a certain material phase at the interface etc. resulting in stuck bits, open or shorts, or a change in required currents and voltages for switching.

Various concepts have been proposed for PCRAM cells, for example the mushroom cell is known from S. J. Ahn, “Highly Manufacturable High Density Phase Change Memory of 64 MB and Beyond, IEDM 2004, and H. Horii et al. “A novel cell technology using N-doped GeSbTe films for phase change RAM”, VLSI, 2003, and Y. N. Hwang et al “Full integration and reliability evaluation of phase-change RAM based on 0.24 um-CMOS technologies”, VLSI, 2003, and S. Lai et al “OUM—a 180 nm non-volatile memory cell element technology for stand alone and embedded applications”, IEDM 2001, or the edge contact cell by Y. H. Ha et al “An edge contact cell type cell for phase change RAM featuring very low power consumption”, VLSI, 2003 or the micro-trench cell by F. Pellizer et al, “Novel uTrench phase change memory cell for embedded and standalone non-volatile memory applications”, VLSI 2004.

In the following the problem will be described with reference to FIG. 1 and FIG. 2.

FIG. 1 is a schematic drawing of a conventional pillar type PCRAM memory cell 100 having a first electrode 110, which can be named bottom electrode, and a second electrode 120, namely the top electrode, wherein the first electrode 110 serves as anode and the second electrode as cathode. A switching active material 130 is sandwiched between the electrodes 110, 120 so that a current flowing from the anode 110 to the cathode 120 flows through the switching active material 130. Arrows 140 indicate a current flowing from the first to the second electrode when a change in the resistivity of the switching active material 130 is intended and a corresponding voltage is applied to the electrodes 110, 120. As indicated by the equidistant arrows 140, the current density is homogeneous across the switching active material 130 effecting a homogeneous heating of the material 130. Hence there is a volume 150—indicated with zigzag lines—, where the switching active material switches its resistivity, that nearly extends across the entire volume of switching active material and also touches the sidewalls of the volume. That is, the switching active material changes its resistivity in the vicinity of the abutting areas surrounding the volume of switching active material, which in turn can have the unwanted effects mentioned above. Also when using a heater electrode in a mushroom cell arrangement, the switching of the active material occurs close to the interface to the heater electrode, as there is the area of highest current density. (S. Lai et al “OUM—a 180 nm non-volatile memory cell element technology for stand alone and embedded applications”, IEDM 2001). If the active material dimension is smaller than the supplying wire diameter as it is the case for the pillar or in-via cell, and the interface resistance is not dominating, then the switching active material is not expected to change its state in the vicinity of the electrode contacts 110, 120 as these dissipate heat and thus delay the heating of the switching active material close to the electrodes, so that the highest temperature will be reached somewhere between the electrode contacts.

Another problem especially regarding CB memory cells is the comparatively high current when effecting the generation and breaking up of the conductive path. Particularly when breaking up the conductive path a high current flows until the memory cell becomes less conductive.

FIG. 2 is a similar schematic drawing of a conventional pillar type CBRAM memory cell 200, having a top electrode 210 and a bottom electrode 220, wherein the top electrode 210 serves as anode and the bottom electrode 220 serves as cathode. A volume of active material 230 is sandwiched between the electrodes. The active material can be seen as a solid electrolyte, i.e. Ag2-doped GeS or GeSe.

Reference sign 240 denotes arrows symbolizing the current flowing through the switching active material when a change of its resistivity is effected. As in FIG. 1 the arrows are equidistant so as to symbolize the homogeneous current density. As described above by applying a suitable voltage/current to the switching active material a conducting path 250 is produced somewhere in the volume of the switching active material 230. As indicated by the curved arrow 250, the conductive path or conductive bridge between the electrodes can be located somewhere in the volume of the switching active material and, due to embedded clusters of ions in the material may not be straight-lined necessarily. Hence the problem arises—similar to the problem described for the PC memory cell—that the conductive bridge 250 may touch a sidewall of the volume of switching active material 230, which may cause the problems described afore.

Also the very first writing of the cell, i.e. producing a conductive path in the material for the first time, requires a higher current than subsequent write actions, which is due to the fact that upon resetting the cell, i.e. to break up the conducting bridge, the conducting bridge must be broken up at only one spot and thus fragments of the conducting bridge remain in the material which forward a new conducting bridge.

Another unwanted property of conventional CBRAM cells is the high current at the beginning of an erase process, i.e. when breaking up the conductive path. As the conducting bridge is broken up by oxidizing the previously injected Ag a strong field is to be constituted between the electrodes, which causes a strong current as long as the conducting bridge exists, i.e. until it is broken up at one spot.

For these and other reasons, there is a need for the present invention.

### SUMMARY

The present invention provides a memory device having at least one resistively switching memory cell. In one embodiment, the memory cell includes a volume of switching active material and a pair of electrodes being galvanically coupled to the volume of switching active material, wherein the pair of electrodes is adapted to send a current through the volume of switching active material, and at least one gate electrode adapted to cause an electric field penetrating the volume of switching active material. Another embodiment of the invention discloses a method for driving the memory device and a method for producing the same.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a schematic drawing of a conventional pillar or in-via PCRAM cell.

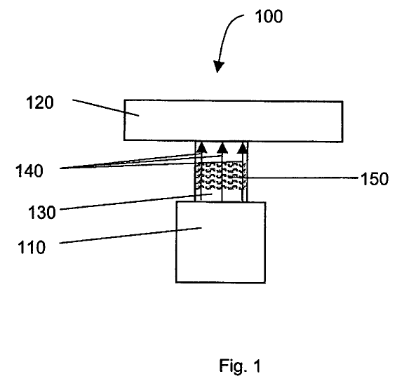

FIG. 2 is a schematic drawing of a conventional CBRAM cell.

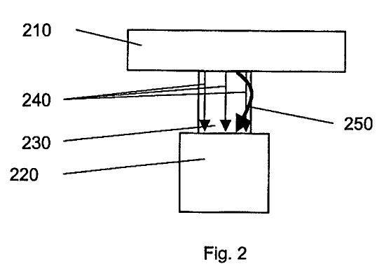

FIG. 3 is a schematic drawing of a PCRAM memory cell having gate electrodes.

FIG. 4 is a schematic drawing of a PCRAM memory cell having gate electrodes showing depletion zones.

FIG. 5 illustrates a schematic drawing of a PCRAM memory cell when reading the cell.

FIGS. 6a, 6b illustrate a schematic drawing of a PCRAM memory cell having individually biased gate electrodes.

FIG. 7 is a schematic drawing of a PCRAM memory cell having two staggered gate electrode means.

FIG. 8 illustrates a schematic circuit diagram of an array of memory cells having gate electrodes;

FIG. 9 illustrates a schematic drawing of a cross sectional view through an array of memory cells having gate electrodes.

FIG. 10 illustrates a schematic circuit diagram of an array of memory cells having gate electrodes and a plurality of gate electrode control lines.

FIG. 11 illustrates a schematic cross sectional view through an array of memory cells having gate electrodes and a plurality of control lines.

FIG. 12 illustrates a schematic view of a CBRAM memory cell having gate electrodes.

FIGS. 13a, b illustrate schematic cross sectional views of CBRAM memory cells having gate electrodes when doping the active material.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides an enhanced memory cell and corresponding memory device, having a switching active material. In one embodiment, the memory device is a PCRAM memory cell. In another embodiment, the memory cell is a CBRAM memory cell.

According to a first embodiment of the invention there is provided a memory device having at least one resistively switching memory cell, the memory cell having a volume of switching active material; a pair of electrodes being galvanically coupled to the volume of switching active material, wherein the pair of electrodes is adapted to send a current through the volume of switching active material; and at least one gate electrode adapted to cause an electric field penetrating the volume of switching active material.

Another embodiment of the invention is directed at a memory device having at least one resistively switching memory cell, the memory cell having a volume of switching active phase change material; a pair of electrodes being galvanically coupled to the volume of switching active phase change material, wherein the pair of electrodes is adapted to send a current through the volume of switching active phase change material; a first and a second gate electrode means adapted to cause a first and a second electric field penetrating the volume of switching active material at a first and a second location respectively, wherein in the direction of the current flow the second gate electrode means is located downstream of the first gate electrode and the second gate electrode means can be used independently from the first electrode means.

Another embodiment of the invention is directed at a method for achieving a change in the resistivity of a volume of switching active, phase change material having sending a heating current pulse through the volume and applying at the same time an electric field causing a depletion zone of charge carriers to the volume to define an area of highest current density.

According to another embodiment of the invention there is provided a method for determining a resistivity value of a volume of switching active, phase change material having the process of applying a voltage to the volume of switching active material to produce a measurement current and applying at the same time an electric field to the volume causing a depletion zone of charge carriers to narrow down an area of highest current density.

Another embodiment of the invention is directed at a method for achieving a change in or for determining a resistivity value of a resistively switching memory cell, the cell having a volume of switching active material galvanically coupled to a pair of electrodes, and at least one gate electrode to cause an electric field in the volume of switching active material upon applying a gate voltage to the gate, wherein a gate voltage is applied to the gate electrode to cause an electric field penetrating the volume of switching active material when a voltage is applied to the pair of electrodes for achieving a change in or for determining the resistivity value of the cell.

Another embodiment of the invention is a method for determining a resistivity value of a resistively switching memory cell, the cell having a volume of switching active material galvanically coupled to a pair of electrodes, and at least one gate electrode to cause an electric field in the volume of switching active material upon applying a gate voltage to the gate, wherein in subsequent processes different gate voltages are applied to the gate electrode to cause an electric field penetrating the volume of switching active material when applying voltages to the pair of electrodes for determining the resistivity value of the cell.

Another embodiment of the invention is directed at a method for achieving a change in the resistivity value of a resistively switching memory cell, the cell having a volume of switching active material galvanically coupled to a pair of electrodes; and at least a first and a second gate electrode means, the second gate electrode means being in the direction of a current flow located downstream from the first gate electrode; and wherein a voltage is applied to one of the first or second gate electrode means to cause an electric field penetrating the volume of switching active material when a voltage is applied to the pair of electrodes.

A further embodiment of the invention is a method for achieving a change in the resistivity value of a resistively switching memory cell, the cell having a volume of switching active material galvanically coupled to a pair of electrodes; and at least a first and a second gate electrode means, the second gate electrode means being in the direction of a current flow located downstream from the first gate electrode; and wherein in subsequent processes a voltage is applied to one of the gate electrode means to cause an electric field penetrating the volume of switching active material when applying a voltage to the pair of electrodes.

Another embodiment of the invention is a memory device having a plurality of resistively switching memory cells, each memory cell having a pair of electrodes and at least one gate electrode to cause an electric field penetrating the switching active material, wherein a plurality a pairs of electrodes of memory cells are galvanically coupled to a continuous volume of switching active material; and wherein the volume of switching active material of a cell is a section of the continuous volume of switching active material.

Still another embodiment of the invention is directed at a memory device having at least one conductive bridge memory cell, the memory cell having a volume of switching active material; a pair of electrodes being galvanically coupled to the volume of switching active material; and at least one gate electrode adapted to cause an electric field penetrating the volume of switching active material, wherein the gate electrode is galvanically coupled to one of the pair of electrodes

Another embodiment of the invention is a method for dissolving the conducting path in a conducting bridge memory cell, the cell having a volume switching active material and a pair of electrodes galvanically coupled thereto and at least a gate electrode adapted to cause an electric field penetrating the volume of switching active material,

wherein a gate voltage is applied to the gate electrode when a voltage is applied to the pair of electrodes, the gate voltage causing an electric field so as to attract ions in the switching active material.

The invention is also directed at an array of resistively switching memory cells, each cell having a volume of switching active material and a pair of electrodes galvanically coupled thereto and at least one gate electrode adapted to cause an electric field penetrating the volume of switching active material, and wherein one of the pair of electrodes is coupled to a bit line or to a ground line by a selection transistor, the other of the pair of electrodes correspondingly coupled to a ground line or a bit line respectively, and wherein the gate of the selection transistor is coupled to a word line and wherein all gate electrodes of the cells are galvanically coupled to a single control line.

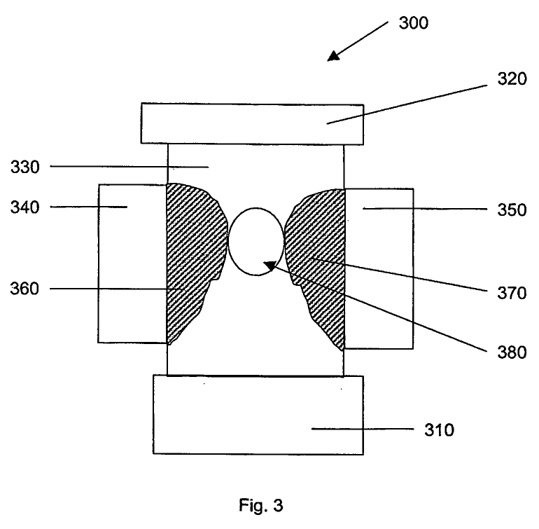

FIG. 3 represents a schematic drawing of a memory cell 300 having a pair of electrodes, namely a bottom electrode 310 and a top electrode 320, and a volume of switching active material 330. The switching active material in this case is phase change material such as an appropriate chalcogenide compound, for example Ge—Sb—Te (GST) or an In—Sb—Te compound, and is galvanically coupled to the pair of electrodes 310, 320, so that a current may flow through the volume of switching active material 330 when a voltage is applied to the pair of electrodes.

Reference signs 340 and 350 denote a first and a second gate electrode. The gate electrodes are located at sidewalls of the volume of switching active material 330.

Upon writing the memory cell, that is to change its resistivity state by heating the switching active material by sending a heating current pulse through the material by applying a positive voltage to the top electrode 320 and ground potential to the bottom electrode 310, a positive gate voltage is applied to the gate electrodes 340, 350 at the same time. The positive gate voltage causes an electric field penetrating the switching active material causing the generation of depletion zones 360, 370 starting from the gate electrode contacts 340, 350. The depletion of charge carriers in the depletion zones 360, 370 affects that these will be not or almost not conducting. Consequently, if a current will flow between the pair of electrodes 310, 320 when a voltage is applied to them, then this current will not flow through the depletion zones 360, 370, but in the area 380 located between the depletion zones 360, 370. In this way, i.e. by applying a gate voltage to the gate electrodes 340, 350, the location of the current flow can be influenced.

As illustrated in the drawing there is an area 380 in the switching active material between the two depletion zones 360, 370, which will allow a current flow. Consequently this area 380 will be the area of the highest current density, so that this will be heated most causing the switching active material to change its resistivity in this area 380. The volume of switching active material 330, which actually switches its resistivity, is thus controlled by the size of depletion zones 360, 370 which in turn is controlled by the applied gate voltages. Furthermore—as described afore—this volume is not located in the vicinity of the top or bottom electrode, but somewhere in between, because the electrodes dissipate heat.

As the volume of switching active material, which actually switches its resistivity, is significantly smaller compared to the volume without control by the gate voltage the amplitude of the heating current can be significantly reduced. Furthermore the amount of energy in the form of heat, which must be dissipated from the cell and thus from the memory device is significantly smaller hence reducing cooling problems of the memory device.

Another advantage of using a gate electrode is that the area of the highest current density can be positioned in the center of the volume of switching active material 330 thus protecting the sidewalls of the memory cell and avoiding the afore mentioned problems.

As illustrated in the drawing two or even more gate electrodes can be used for bordering the area 380 wherein the switching active material actually changes its resistivity.

In a first embodiment two gate electrode contacts can be used, which are preferably located at opposite surfaces of the volume of switching active material 330, so that the area 380 is in the center of the volume 330. For an even more exact positioning a plurality of gate electrodes can be used, which preferably are located equidistant around the circumference of the volume of the switching active material and in the direction of the current flow at the same height.

In a further embodiment a single gate electrode surrounding the volume of switching material can be used, wherein the gate electrode can be for example a plate of conducting material with vias to incorporate the gate electrode and active material.

Generally the principle of using a gate electrode in a resistive memory cell to generate a depletion zone in the switching active material to influence the size and location of the volume of actually switching material can be used to prevent a substantial current flow from being close to a sidewall of the switching active material, so that the principle also can be used for protection purposes.

A gate electrode 340, 350 can be in direct contact to the semiconducting active material 330, forming a p-n junction or a Schottky contact or most preferred in indirect contact through a metal-insulator-semiconductor (MIS) surface, to prevent a current flow through the gate electrodes. For p-type active material pn-type junctions a positive gate voltage will be applied to the n-type gate electrodes for generating the depletion zone. Vice versa, if the active material is n-type, a negative gate voltage will be applied to a p-type gate electrode for controlling the depletion zone.

Although in this embodiment an in-via or pillar type cell has been described, any other cell type is suitable which allows the gate electrodes to be placed so that the electric field can penetrate the volume of switching active material between the pair of electrodes and thus causes a depletion zone influencing the location of the highest current density.

When a memory cell has been written as described afore, the volume 380, that is where the material actually changed its resistivity, is only a fraction of the entire volume of switching active material placed between the pair of electrodes. Consequently, for reading the memory cell, i.e. determining the state of resistivity of the cell, the gate voltage has to be applied also. Otherwise, when applying a test voltage between the pair of electrodes 310, 320 and without applying a gate voltage to the gate electrodes 340, 350, a current could flow in the areas which were depletion zones when writing the cell, but are now conducting. This would lead to erroneous results.

Therefore, a gate voltage, preferably of the same amplitude when writing the cell, must be applied to the gate electrodes 340, 350 for reading the cell.

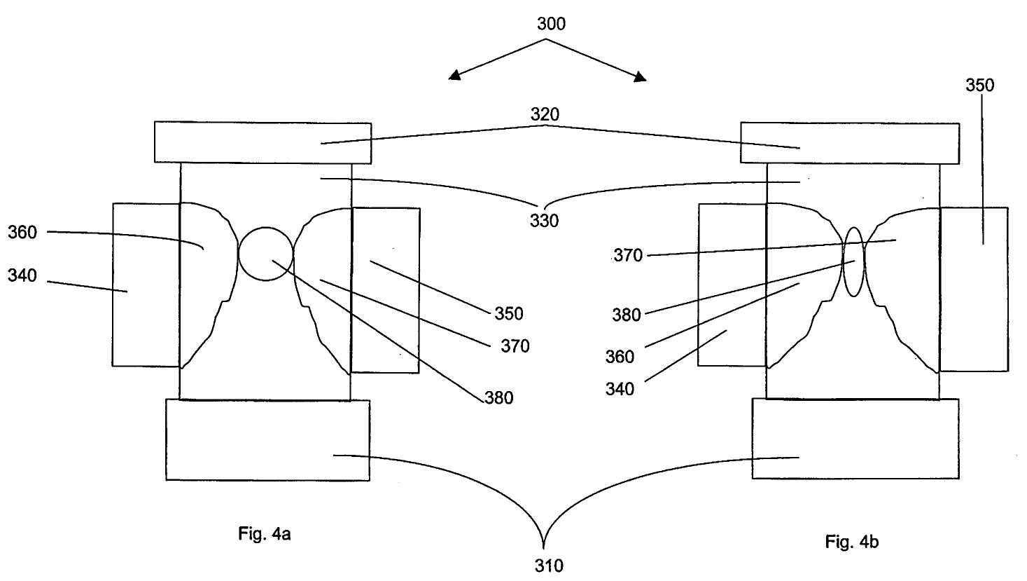

Turning now to FIGS. 4a and 4b another aspect of the invention is described in the following. Both figures represent schematic drawings of a resistive memory cell, which is identical to the cell of FIG. 3 with the exception of the state of the cell, therefore the same reference signs will be used here.

FIG. 4a illustrates the memory cell as described in FIG. 3, wherein a first gate voltage is applied to the gate electrodes 340, 350 causing depletion zones 360, 370. If at the same time a voltage is applied to the pair of electrodes 310, 320 to write a value to the cell, that is to generate an area 380 of high resistance, then an area 380 having the size as indicated, is generated. Thus the size of the depletion zones 360, 370 define the size of the area 380.

Turning now to FIG. 4b the amplitude of the gate voltage has been increased when writing the cell. Consequently the electric field—not illustrated explicitly in the drawing—is stronger and the depletion zones 360, 370 penetrate deeper into the volume of switching material 330. Thus the highly resistive area 380 is significantly smaller than in FIG. 4a.

The intended consequence of applying a higher gate voltage to the gate electrodes 340, 350 when writing the cell is primarily the reduced size of area 380. As a side effect the current necessary for triggering the change in the resistivity is smaller.

As the size of area 380 thus depends on the applied gate voltage a plurality of different sizes of area 380 can be stored in the memory cell. Consequently in this way a plurality of different resistivity levels can be stored in one such cell, as will become clear in the following.

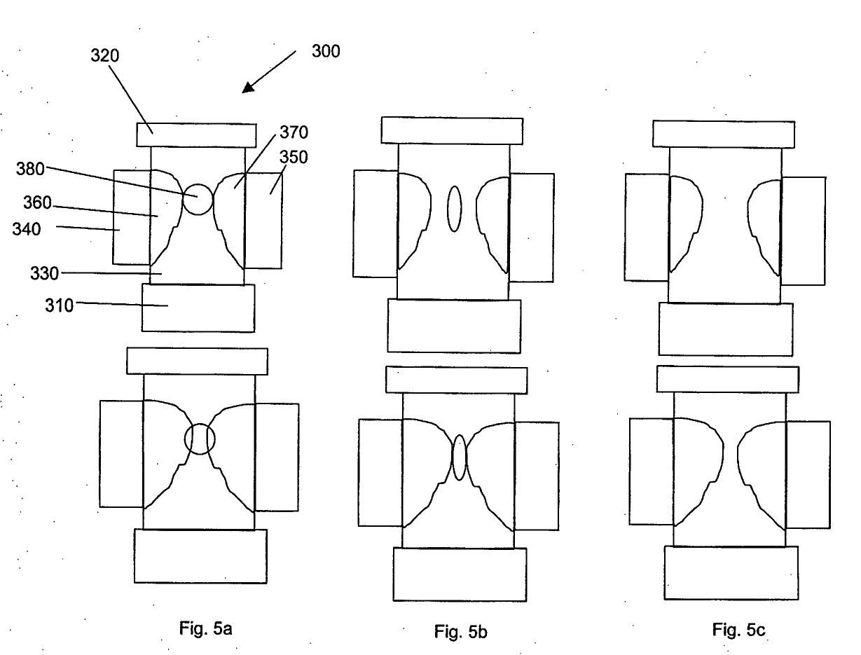

In FIGS. 5a-5c the method processes for determining the resistivity value of such a memory cell is illustrated. In this embodiment it is assumed, that area 380 can have two different sizes. For reasons of clearness in FIGS. 5a-c the same reference signs as used for FIGS. 3, 4 are used and drawn in for the upper drawing of FIG. 5a only.

The size of area 380 can be determined by executing—in this case—two subsequent method processes. In each of the processes one of the different gate voltages used when writing a resistivity level is applied and the resistivity of the cell is measured.

In FIG. 5a there is an area 380—corresponding to that in FIG. 4a—wherein the resistivity of the phase change material is high. The size of area 380 is the biggest of all FIGS. 5a-5c. In the first process, represented in the upper drawing of FIG. 5a, the gate voltage used for writing that resistivity level is applied. The resulting depletion zones 360, 370 are of the same size as when producing the area 380, so that the depletion zones “touch” the area 380. Hence a current flowing between the pair of electrodes 310, 320 when applying a test voltage to the pair of electrodes must pass that area 380. Consequently a high resistivity value is determined in the first process.

In the subsequent second process, represented in the lower drawing of FIG. 5a, a higher gate voltage, exceeding the gate voltage applied for producing the actual area 380, is applied to the gate electrodes. Correspondingly the depletion zones 360, 370 not only touch but penetrate the area 380. The current flowing between the pair of electrodes 310, 320 is thus forced to pass the area 380, hence also a high resistivity is detected.

In FIG. 5b there is an area 380—corresponding to that of FIG. 4b—which has been produced using a higher gate voltage than in FIG. 5a. In order to determine the size of the area 380 the same method processes as described before are executed. That is in the first method process—as represented in the upper drawing of FIG. 5b—the resistivity value of the cell is measured when applying the first gate voltage, which in this case is lower than the gate voltage used for producing the area 380. Consequently there is an area of low resistive material between the—smaller—area 380 and the depletion zones 360, 370. A current flowing between the pair of electrodes 310, 320 therefore does not have to flow through area 380 but can find a less resistive pathway alongside. Hence a low resistivity value is determined in this configuration.

In the subsequent second method process—represented in the lower drawing of FIG. 5b—the gate voltage applied for producing the actual size of area 380 is applied to the gate electrodes 340, 350. Consequently the depletion zones 360, 370 are of that size when producing the area 380 and thus “touch” the area. When measuring the resistivity value a high value is detected.

In FIG. 5c there is no area 380 of switching material being in the highly resistive state. Consequently when determining the resistivity values in the method processes a low resistivity value will be detected in both method processes.

Summarizing the above the size of the area 380 can be defined by applying different gate voltages and can be determined by the afore described method processes. In this way different resistivity values or resistivity levels can be stored in one memory cell, so that a multi-level cell is created.

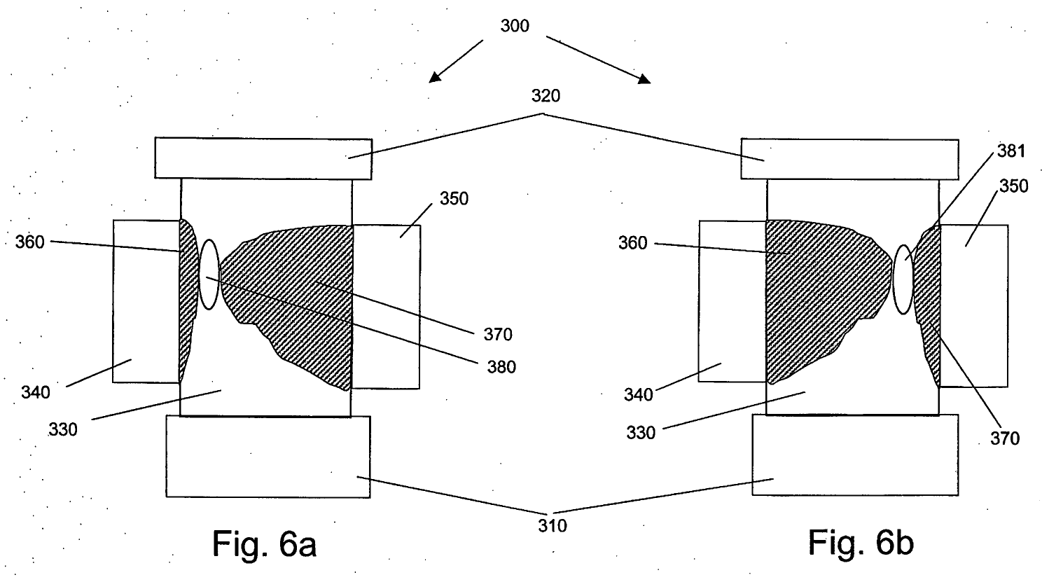

In FIGS. 6a, 6b a variation of the memory cell described afore is represented having similarities to the cell of FIG. 3, so that the same reference signs are used for same items. The schematic drawing of FIG. 6a illustrates a memory cell 300 having a bottom and a top electrode 310, 320 and switching active material 330 sandwiched between the electrodes. Furthermore the cell 300 includes a first gate electrode 340 and a second gate electrode 350, wherein a gate voltage can be applied to each of the gate electrodes separately, thus the gate electrodes can be biased independently from each other.

In FIG. 6a a first gate voltage Vg1 is applied to gate electrode 340 and a second, different gate voltage Vg2 with Vg1>Vg2 is applied to the second gate electrode 350. According to the higher gate voltage Vg1 the depletion zone 370 penetrates deeper into the switching active material than the depletion zone 360 caused by the lower gate electrode voltage Vg2. The area 380 between the depletion zones 360, 370, which defines the area of the highest current density is thus moved from the center of the cell to a location closer to the gate electrode having the lower gate voltage applied.

FIG. 6b illustrates the opposite case, in which the gate voltage Vg1 applied to gate electrode 340 is significantly higher than gate voltage Vg2 applied to the remaining gate electrode 350. Consequently the depletion zones 360, 370 define an area 381 being the area of the highest current density located at another location in the volume of switching active material 330.

The location of the area 380, 381 of the highest current density can thus be controlled by applying different gate voltages Vg1, Vg2 to the gates 340, 350 when writing a cell. In this way at least two areas 380, 381 can be generated or deleted between the gate electrodes 340, 350, wherein each of the areas 380, 381 can be assigned an independent logic value.

When reading a cell, the same gate voltages must be applied to the gate electrodes as applied when writing the cell, so that the depletion zones correspondingly define the areas 380, 381 of the highest current density.

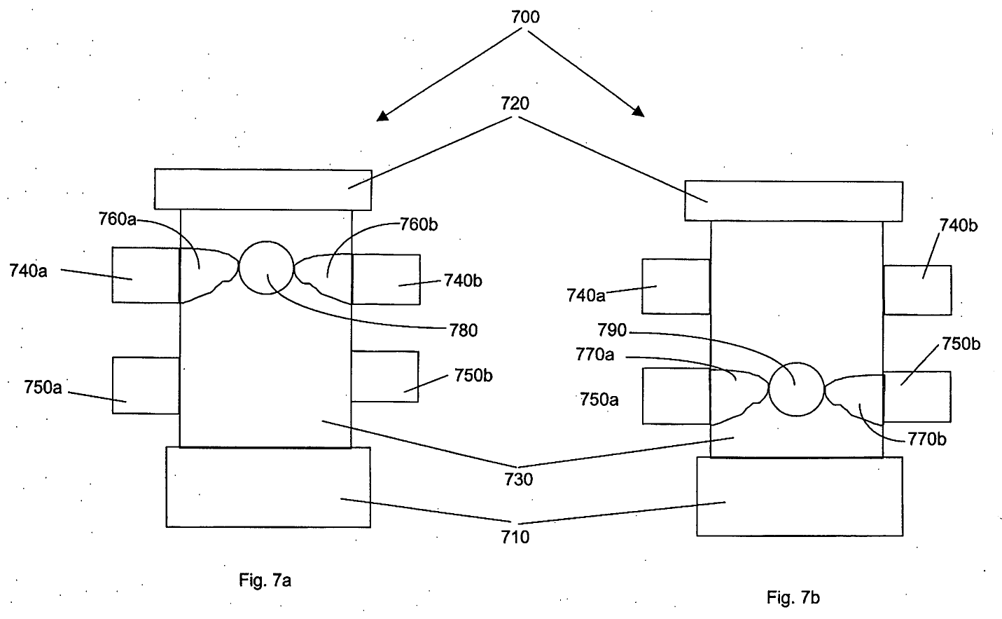

With regard to FIGS. 7a and 7b another topic of the invention will be described. The drawings represent a resistive memory cell 700 having a pair of electrodes, namely a bottom electrode 710 and a top electrode 720, and a volume of switching active phase change material 730 being initially in a conductive state and galvanically coupled to the top and bottom electrode.

In contrast to the cells described afore this memory cell 700 includes a first gate electrode means 740 and a second gate electrode means 750, wherein one of the gate electrode means is in the direction of the current flow located downstream from the other gate electrode means. As in this embodiment it is assumed that the top electrode 720 serves as cathode and the bottom electrode 710 serves as anode, the direction of the current flow is from the top electrode 720 to the bottom electrode 710. Therefore the second gate electrode means 750 is located—with regard to the direction of the current flow—downstream of the first gate electrode 740.

Each gate electrode means includes at least one gate electrode being located so that an electric field emerging from an electrode causes a depletion zone in the switching active material as described afore with reference to FIG. 3 to FIG. 6. In a preferred embodiment and as illustrated in the drawings each gate electrode means 730, 740 includes two gate electrodes, 740a, 740b and 750a, 750b respectively. Gate electrodes 740a and 740b are galvanically coupled; also gate electrodes 750a and 750b are galvanically coupled. Preferably and as illustrated in the drawings, the gate electrodes of a gate electrode means are located at opposite surfaces of the volume of switching active material 730. Other configurations of gate electrode means having even more electrically coupled gate electrodes can be suitable for the exacter location of the an area 780. For example a plurality of electrically coupled gate electrodes being located—like a ring—equidistant and in the direction of the current flow at the same height around the volume of switching material 730. In another embodiment a gate electrode means can be arranged as a single electrode surrounding the volume of switching active material.

The first gate electrode means 740a, 740b can be driven separately from the second gate electrode means 750a, 750b, that is the gate electrode means are electrically decoupled and a gate voltage can be applied to a gate electrode means independently from applying a gate voltage to the other gate electrode means.

Similar to the resistive memory cells described afore depletion zones 760a and 760b penetrate the volume of switching active material 730 when applying a gate voltage to the electrodes 740a and 740b of the first gate electrode means. The depletion zones 760a and 760b encircle a first area 780, which—similar as described afore—will be the area of the highest current density when applying a voltage to the pair of electrodes 710, 720 to write the cell 700. The second gate electrode means, namely the gate electrodes 750a and 750b, remains without any gate voltage so that they do not generate depletion zones. The residual volume of the switching active material remains in the initial conductive state.

In the schematic drawing of FIG. 7b the gate electrodes 740a, 740b remain without voltage, whereas a gate voltage is applied to the gate electrodes 750a, 750b. The voltage applied to the pair of electrodes 710, 720 causes a current to flow between the electrodes of the pair. Caused by the gate voltage applied to the gate electrodes 750a, 750b the depletion zones 770a, 770b define an area 790 being the area of the highest current density in which—as described afore—the phase change material will change its resistivity.

In this way two highly resistive areas 780, 790 can be generated in two subsequent method processes, wherein the generation of a highly resistive area is independent from the generation of another highly resistive area.

The reading of the cell 700 can be performed in two subsequent processes. In a first process, a gate voltage, namely the gate voltage applied when writing, is applied to the gate electrodes 740a, 740b and a comparatively low test voltage is applied to the pair of electrodes 710, 720. The gate electrodes 750a, 750b remain without voltage. Consequently a current will flow between the electrodes 710, 720 and through area 780, but can flow outside the area 790 through switching active material being in the conductive state. In this way the method process serves to determine the resistivity value of the cell with regard to the first gate electrode means 740.

Subsequently the resistivity of area 790 can be determined by applying a gate voltage to gate electrodes 770a, 770b and a test voltage to the pair of electrodes 710, 720 and measuring the amplitude of the current flowing.

Thus by performing these method processes as described the resistivity of the areas 780 and 790 can be determined.

As each of the areas 780, 790 can be assigned a bit value, the described memory cell can store two bits, which can be written and read independently.

The principle can be expanded to a phase change memory cell having a plurality of gate electrode means, which can store a plurality of bits, so that a multi-bit cell is created.

Although in the drawings of FIGS. 7a, 7b a pillar or in-via style cell is illustrated and has been described, the principle can be used with other cell types allowing a gate electrode means to be placed to define an area of the switching active material, wherein the switching active material actually will change its resistivity.

Furthermore a combination of the afore described principles is possible, namely a combination of the afore described multi-level cell and the multi-bit cell. Such a cell includes a volume of switching active material being galvanically coupled to two electrodes for sending a heating current pulse through the switching active material and a plurality of gate electrode means. The gate electrode means can be used to form zones wherein the resistivity of the switching active material actually switches its state, wherein different voltages can be applied to each gate electrode means to vary the size of the zones. In this way a multibit and multilevel memory cell can be created.

In another variation—not shown—of the memory cell described with reference to FIG. 7 there are at least four gate electrodes being staggered in two pairs in the direction of the current flow. So for example a first pair of gate electrodes is located at opposing surfaces of the volume of switching active material and a second pair of electrodes is located downstream—in the direction of the current flow—at opposing surfaces of the volume of switching active material. A gate voltage can be applied to each of the gate electrodes individually. Consequently one can define areas of highest current density individually between the gate electrodes of the first or second pair respectively by applying individual gate voltages as described with reference to FIG. 6, wherein there can be read or write access to one area at a time. This principle can be expanded to using a plurality of gate electrodes, wherein a gate voltage can be applied to each of the gate electrodes individually and wherein the gate electrodes are spread around the circumference of the switching active material and staggered in the direction of the current flow.

Another embodiment of the current invention is directed at a high-density memory cell array and structure of PCRAM cells with field-assisted current constriction as described afore.

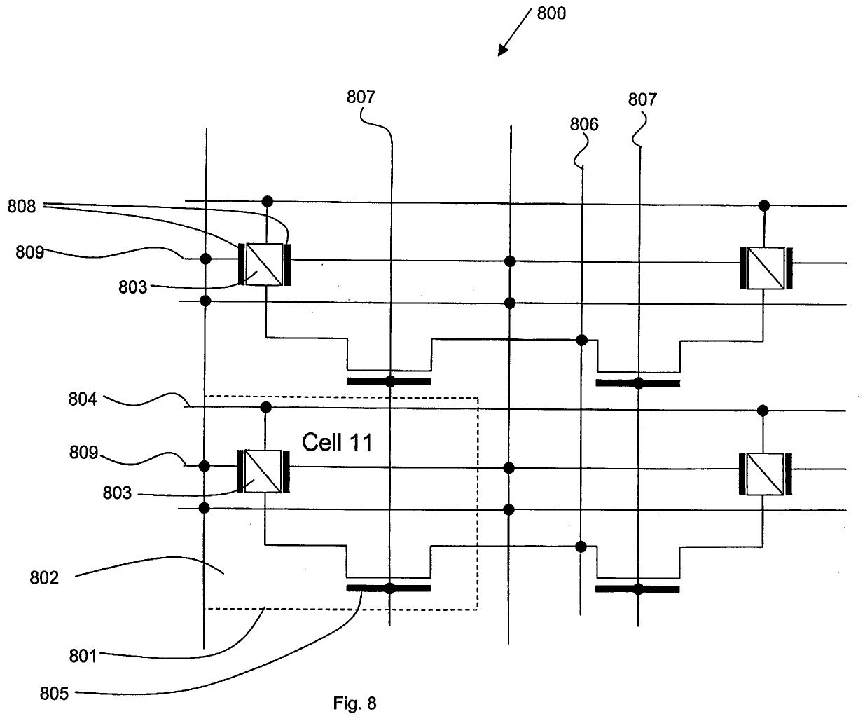

FIG. 8 illustrates a schematic circuit diagram 800 of four memory cells being representative for the array.

Each memory cell 802—one is encircled by the dotted line 801—includes a volume of switching active material 803, which is, because of its varying resistivity represented by the corresponding symbol. The volume of switching active material 803 is coupled via a first electrode—not explicitly illustrated in the drawing—to a bitline 804 and via a second electrode—also not shown—to the drain of a selection transistor 805, which in turn is coupled to a ground line 806 and is triggered by a wordline 807.

Each cell includes a pair of coupled gate electrodes 808, being—for example as illustrated in the drawing—located on opposite surfaces of the volume of switching material 803. The gate electrodes 808 are coupled to a control line 809, with which a gate voltage can be applied to the gate electrodes 808. Similar to the gate electrodes described for PCRAM a single gate electrode surrounding the volume of switching active material can be used, so that there may be only one wire to the gate electrode.

If the selection transistor 805 is opened by a corresponding signal on the wordline 807, and if furthermore the bitline 804 has an appropriate voltage, then a current can flow from the bitline 804 through the volume of switching active material 803 and the selection transistor 805 to the ground line 806. As described afore by applying a gate voltage to the gate electrodes 808 the area of the highest current density can be controlled, allowing to influence the area of the highest current density as described with regard to FIGS. 3 to 5.

As illustrated in the drawing the gate electrodes 808 of all memory cells 802 are coupled together, as in this embodiment they are formed as a patterned plate of conducting material, the plate thus forming the control line 809.

The advantage of this wiring, that is all gate electrodes are galvanically coupled, is that there is only one additional contact for applying a gate voltage to the gate electrodes 808 of a plurality of memory cells 802.

In a variation—not shown—of this wiring the bitline can be coupled to the source of the selection transistor and the drain of the selection transistor can be coupled galvanically by an electrode to the switching active material.

However, the wiring of all control lines 809 in one plate may involve a big parasitic capacitance or increased leakage currents and does not allow individual biasing of the control gate electrodes, which is not desirable for low power or fast or multilevel applications.

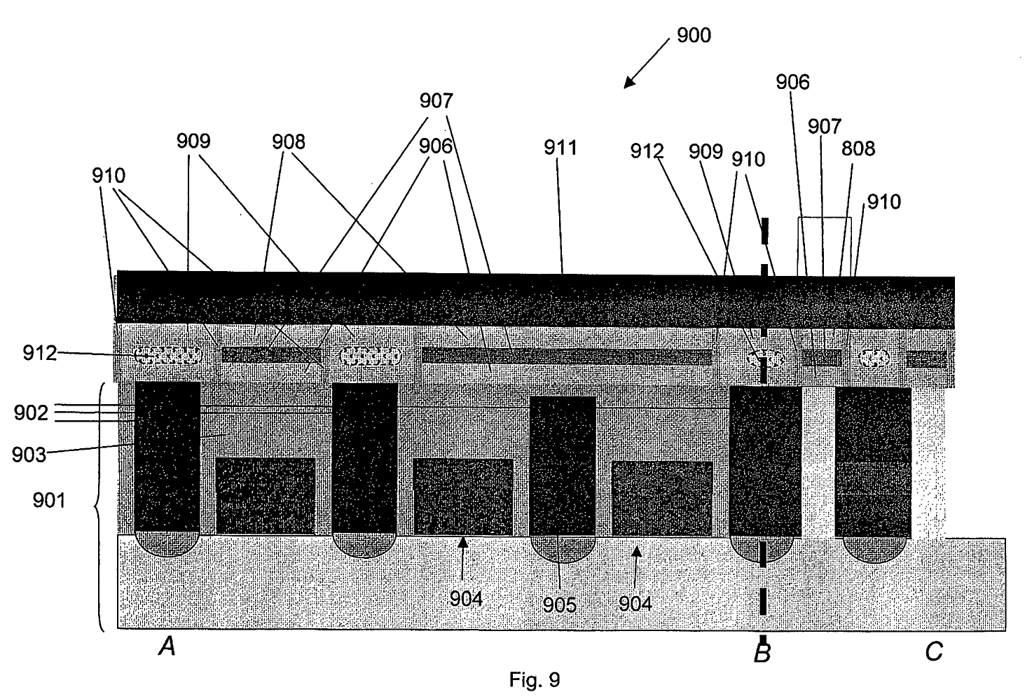

FIG. 9 illustrates a schematic drawing of a cross sectional view through an array of memory cells having control gate electrodes, wherein the control gate electrodes are formed as a patterned plate as described with regard to FIG. 8. It is to be noted, that the cut line A-B is perpendicular to the cut line B-C. That is, if cut line A-B is parallel to the paper plane of the drawing, then the view along cut line B-C is directed into the paper plane. The dotted line at B denotes the shift in the direction of the cut line.

The array of memory cells is formed on the planar surface of a substrate 901, wherein the substrate provides for electrode contacts 902, made of e.g., tungsten (W) or any other conventional metal, embedded in an electrically and thermally insulating material 903 being SiO2 or any other suitable insulating material. Furthermore there are selection transistors 904 connecting the contacts 902 with a ground line 905, which runs as a line into the paper plane, that is parallel to the cut line B-C.

The generation of the memory cells onto the surface of the substrate 901 can be performed by two alternative methods, which will be described in the following.

In the first method the control lines are created before the switching active material is deposited. The method starts with the deposition of a first insulating layer 906, subsequently the deposition of the control line layer 907 and subsequently by the deposition of a second insulating layer 908 covering the control line layer 907. The first and second insulating layers 906 and 908 can be formed of any suitable dielectric, e.g., SiO2 or SiN or Al2O3. For the control line layer 907 a conducting element can be used, for example poly Si or a conducting metal like tungsten (W) or aluminum (Al) or copper (Cu) or Titanium nitride (TiN). These layers can be deposited using conventional methods such as chemical vapor deposition (CVD).

Next, the stack of the three layers 906, 907, 908 will be patterned to form openings that is vias or trenches, on top of the contacts 902. As these openings will serve as volumes to place the switching active material 909 in, the patterning must bare the contacts 902, so that on top of the surface of a contact 902 an electrode contact to the switching active material 909 can be formed. The patterning can be performed in one process using any conventional lithographic and etching method. In this way a stack of three layers forming vias or trenches is formed, wherein the middle layer is the control line.

In the next process a gate insulator layer 910, which can be any suitable dielectric, is deposited by using any suitable conventional method e.g., CVD, wherein the layer 910 must be deposited on the sidewalls of the vias or trenches for electrically insulating the switching active material 909 from the conducting control line layer 907. A subsequent conventional anisotropic spacer etching is then used to remove the gate insulator layer 910 form horizontal surfaces, so that at least the contacts 902 are again bare and can connect to an electrode contact.

Then the switching active material 909 is deposited using a conventional process, such as CVD and optionally planarized using also a conventional method such as chemical mechanical polishing (CMP), so that switching active material deposited onto the second insulating layer 908 is removed and a planar surface with embedded volumes of switching active material 909 is achieved.

In a further process a conducting metal, e.g., tungsten, is deposited using a conventional method as denoted afore and patterned subsequently using a conventional method such as an lithographic etching process to form top electrode contact and bitlines 911 to connect to the volumes of switching active material 909, wherein the bitlines 911 are orthogonal to wordlines.

From this method an alternative method differs in that now the switching active material is deposited before the layer for the control line is deposited. This alternative method starts with depositing the layer of switching active material 909, the stack 909 optionally containing layers of conducting bottom and top electrode material, and optionally a layer of hardmask material, which is not illustrated in the drawing. Any suitable method, such as CVD, can be used to deposit each of the layers.

These layers are then patterned using a conventional lithographic and etching method to form pillars or lines of switching active material 909, which couple to contacts 902.

Subsequently a gate insulating layer 910 is deposited or formed.

In the following the stack of the control line is formed, preferably by a sequential deposition and etchback of a first insulation layer 906, the deposition and etchback of the conducting control line layer 907 and the deposition of second insulating layer 908. The method to deposit these three layers may be any conventional process, e.g., CVD. After the second insulating layer 908 has been deposited the surface is planarized using a conventional planarizing method such as CMP, wherein the planarization process is stopped when the optional hardmask material layer is reached or, in case there is no hardmask layer, when the bitline 911 layer is reached. If not already happened, the gate insulating layer is removed from the top of the active layer stack at this point.

Subsequently the bitlines 911 are formed. That is, if the optional hardmask material has been deposited, this is removed by any conventional method. Subsequently the bitline material layer 911 is patterned using any conventional method to form bitlines being preferentially orthogonal to the wordlines—not shown—.

Reference sign 912 denotes an area of highest current density within the switching active material 909, wherein the switching material 909 will actually change its resistivity when writing the cell and which also defines the resistivity of the cell when determining the state of, that is reading, the memory cell.

In this way, by using either method, an array of in-via or pillar style memory cells can be formed, wherein each memory cell includes a circumferential gate electrode and all gate electrodes are coupled together.

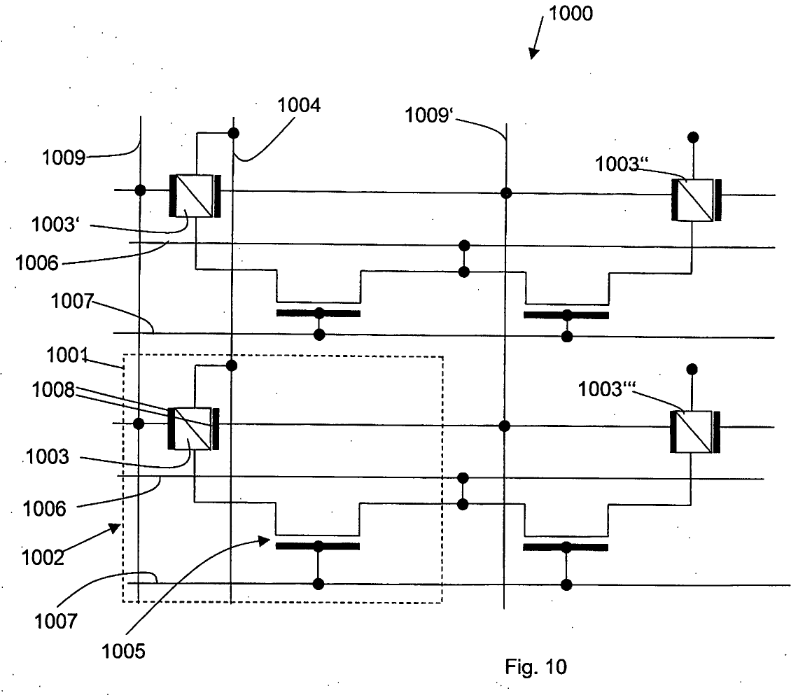

Another circuit diagram offering a wiring for the gate electrodes with smaller parasitic capacities and independently biasable control gate electrodes, i.e. an individual gate voltage can be applied to a gate electrode, is represented in FIG. 10. Similar to the circuit described before the circuit 1000 of FIG. 10 represents a memory cell 1002 encircled by the dotted line 1001. The memory cell 1002 includes a volume of switching active material 1003 being coupled via a first electrode—not shown—to a bitline 1004 and a second electrode to a selection transistor 1005 connected to a ground line 1006 and a word line 1007. A current for changing the resistivity of the volume of switching active phase change material will flow if the selection transistor 1005 is opened by a signal on the wordline 1007 and an appropriate voltage is applied to the bitline 1004.

Different from the circuit described in FIG. 8 in this circuit diagram there are several control lines 1009, 1009′ not being electrically coupled and parallel to the bitlines 1004. Each control line connects to one gate electrode of a cell of two adjacent columns of cells, wherein the gate electrodes of one column are opposing the gate electrodes 1008 of the adjacent column of memory cells. For example control line 1009′ connects to the right hand gate electrode of volume 1003′ and to the left hand gate electrode of volume 1003″ and also to the left hand gate electrode of volume 1003 and to the right hand electrode of volume 1003′″.

In this way, as a control line couples to significantly less gate electrodes than in the circuit diagram of FIG. 7, the parasitic capacities coupled to a control line 1009 are significantly smaller.

Upon writing or reading a memory cell and for applying a gate voltage to the gate electrodes, a voltage has to be applied to two control lines, which in total are coupled to a fraction of the number of gate electrodes on the chip, so that the parasitic capacities to be loaded when applying a gate voltage is significantly decreased or the two gate electrodes can be biased to different voltages to control the location of active switching material.

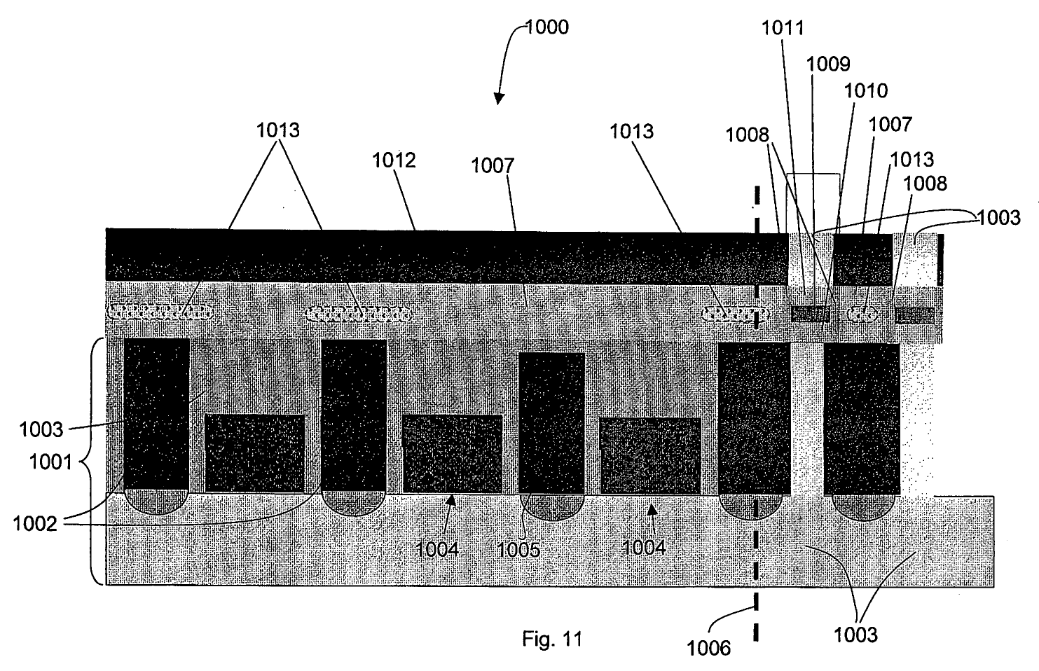

FIG. 11 represents a schematic cross sectional view through an array of phase change memory cells 1100 having gate electrodes, wherein there is a plurality of control lines to apply voltage to the gate electrodes.

Similar to the drawing of FIG. 9 the memory cells are created on a substrate 1101 providing a planar surface with embedded electrode contacts 1102, made of e.g., tungsten or any other conventional metal, embedded in an electrically and thermally insulating material 1103, such as SiO2 or any other suitable, conventional insulating material. Also, there are selection transistors 1104 connecting the contacts 1102 with a ground line 1105.

The dotted line 1106 denotes a change in the direction of the cut line. That is the cut line A-B is perpendicular to the cut line B-C. So if cut line A-B is parallel to the paper plane of the drawing, then the cut line B-C is directed into the paper plane.

The switching material 1107 of the memory cells, in this case phase change material, is deposited onto the substrate 1101 and patterned into lines, wherein the lines are placed above the contacts 1102. As each of the contacts 1102 is an electrode for applying a voltage to the phase change material when changing the resistivity or detecting the resistivity of a cell, a plurality of memory cells thus share one line of switching active material 1107.

Along the lines of switching material 1107 a—vertical—gate insulating layer 1108, e.g., a layer of any suitable dielectric, is formed. Also along the lines of switching active material 1107 and running between two parallel lines of switching active material 1107 a control line 1109 is formed being sandwiched by a first and a second insulating layer 1110, 1111 respectively. The gate electrode surfaces for a memory cell are thus formed by the vertical side of a control line 1109. Corresponding to the circuit diagram of FIG. 9 a control line 1109 in this way couples the gate electrodes of a first and a second row of memory cells, namely by forming the gate electrode surfaces with its two vertical sides.

On top of the lines of switching active material 1107 a layer of a conducting material is deposited and patterned to form bit lines running parallel to the lines of switching active material 1107.

The control lines 1109 can be contacted for further wiring for example at the end of the array of memory cells; which is not illustrated in the drawing. Also the next layers on top of the bit line 1112 are not illustrated.

In the direction as illustrated in the drawing left from the dotted line 1106 the cells are formed like mushroom cells with the volume of switching active material 1107 and the contact on top, namely the bit line 1112, larger than the contact 1102 below. In the perpendicular direction, as illustrated in the drawing on the right hand side of the dotted line 1106, the dimension of the switching active material 1107 is the same or smaller as the contact 1102 below and the contact, namely the bit line 1112, on top and is thus in this direction formed like a pillar cell.

Reference sign 1113 denotes schematically the area of “actively” switching active material, which is the area in which the phase change material actually changes its state when applying an voltage to the electrode contact 1102 and the bitline 1112 effecting an heating current pulse. The size and geometry of this area 1113 is defined by the position of the electrodes between which the heating current pulse flows, by the position of the gate electrodes being in this embodiment the vertical sides of the control lines 1109, and of the size of the depletion zones generated by applying a gate voltage. In this way a plurality of memory cells share a line of phase change material 1107.

In the embodiment of FIGS. 8-11, a memory array has been described where the bitline is electrically directly coupled to one electrode of the memory cell, the second electrode being coupled to one node of the selection transistor. In another embodiment, the bitline may be electrically directly coupled to one node of the selection transistor, the memory element being coupled to the other side of the transistor and to a common plate electrode. Also in this case, a control gate electrode as described in FIG. 8-11 can be formed at the sidewalls of the memory cell. The memory array has been described for a PCRAM cell, but is also applicable to other resistive memory cell like conducting bridge.

Another object of the invention is directed at a resistive memory cell of the conducting bridge type.

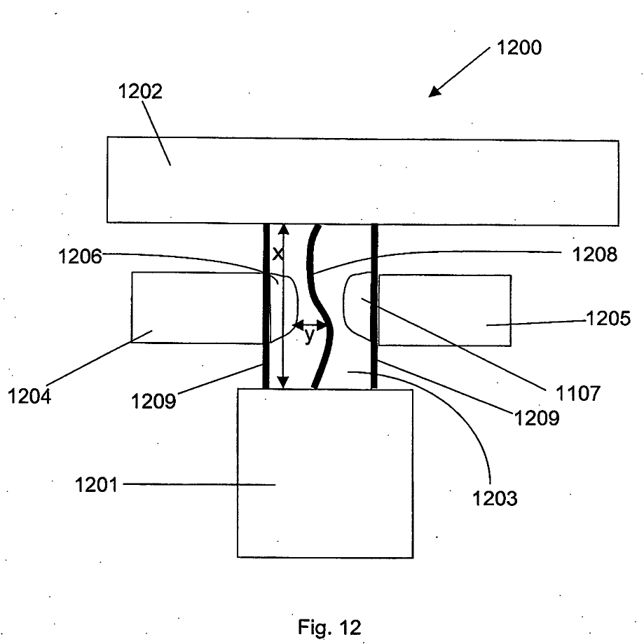

FIG. 12 represents an exemplifying embodiment according to this aspect. A cell 1200 includes a bottom electrode 1201 and a top electrode 1202, which may be of silver (Ag) or copper (Cu). A volume of switching active material 1203, in this case a solid-electrolyte such as metal-doped chalcogenide, e.g., a silver (Ag) doped chalcogenide, or an oxide glass or any other suitable material, is located between the pair of electrodes 1201, 1202. A first and a second gate electrode 1204, 1205 are located at the sidewalls of the volume of switching active material 1203. The gate electrodes 1204, 1205 are galvanically insulated against the volume of switching material by a insulating layer 1209, e.g., the gate electrodes can be formed by a metal-insulator-semiconductor (MIS) structure.

When writing the cell, that is when a conducting bridge 1208 between the top electrode 1202 and the bottom electrode 1201 should be generated through the switching active 1203 material to convey the cell 1200 in a conductive state, a positive voltage Vwrite is applied the top electrode 1202, wherein it is assumed that the bottom electrode 1201 has ground potential i.e. 0V.

At the same time a positive gate voltage is applied to the gate electrodes 1204, 1205, which generates a gate field penetrating the switching active material and consequently causing depletion zones 1206, 1207 in the switching active material 1203 in front of each gate electrode 1204 and 1205. Due to the depletion zones 1206, 1207 the ions, i.e. the Ag-ions, leaving the top electrode 1202 will avoid to approach the sidewalls of the switching active material 1203. Instead they will prefer a pathway through the area of the lowest depletion, which is the center of the volume of switching active material 1203. Also, the positive ions, i.e. the Ag+ ions solved in the solid electrolyte, will be driven towards the lower field strength, being in the center of the switching active material 1203. Hence the concentration of ions quickly increases in the center of the volume of switching active material thus accelerating the forming of a conductive bridge 1208.

Consequently by applying a gate voltage with the same polarity as the anode being the top electrode 1202 in this embodiment to the gate electrodes 1204, 1205 the forming of a conducting bridge 1208 in the center of the volume of switching active material 1203 is accelerated. Furthermore the location of the conductive bridge, which is the pathway the current flowing between the pair of electrodes 1201, 1202, can be influenced thus preventing that the current flow touches a sidewall of the volume of switching active material.

Preferably the voltage—in the switching active material—between the top electrode 1202 and the upper, i.e. nearest, end of the gate electrodes 1204, 1205 should be chosen not to exceed the threshold voltage Vt in order to prevent the generation of a parasitic conducting path between the top electrode and a gate electrode. This is especially important if non-ideal insulating dielectrics or tunnel barriers are used for insulating the gate electrodes.

Furthermore in order to work properly the geometric dimensions should be chosen so that the distance—in the drawing denoted y—from the depletion zones 1206, 1207 to the conductive path, which is assumed to be located in the center of the volume of switching active material 1203, is smaller than the distance—in the drawing denoted as x—between the top electrode 1202 and the bottom electrode 1201.

For resetting the cell 1200, that is for erasing or at least breaking up the conductive path 1208 between the top electrode 1201 and the bottom electrode 1202, an electric field with opposite polarity as for writing is necessary. That is, for erasing the conductive bridge a negative voltage—again the bottom electrode 1201 remains at ground level in this embodiment—is applied to the top electrode 1202, which is the Ag anode in this case.

In order to accelerate the process a negative voltage is applied to the gate electrodes, which causes an electric field that attracts the Ag+ ions and pulls them aside. Consequently a reduction of the Ag+ ions to Ag can take place, even if the conductive path between the top electrode 1202 and the bottom electrode 1201 is not yet weakened. Thus, with a negative gate voltage applied, the conducting bridge can be broken up faster and/or with lower voltages applied to the top electrode 1202.

Preferably the voltage for breaking up the conductive bridge between the top electrode 1202 and the nearest end of a gate electrode 1204, 1205, which is the interface of a gate electrode to the switching active material—should not exceed the threshold voltage of the switching active material, that is

−|verase|−Vif<Vt,

with Verase being the voltage applied to the top electrode 1202,

Vif being the voltage of the gate electrode (if=interface)

Vt being the threshold voltage for electrochemical oxidation.

On the other hand the voltage between a gate electrode and the bottom electrode 1201 should be at least −Vt to get the redox reaction started.

As described afore the gate voltage principally has the same polarity as the top electrode 1202, so that in a mutation of the embodiment the gate electrodes can be electrically coupled to the top electrode 1202, which can simplify the production process.

In another variation the time of the voltage applied to the top and bottom electrodes 1201 and 1202 respectively can be varied. Although the conducting bridge to great extent decreases the resistance between the top and bottom electrodes it still has a measurable resistance which can be influenced by the time and amplitude of the voltage applied to the top and bottom electrodes. Thus in order to produce a conducting bridge having a very low resistance a high voltage can be applied to the top and bottom electrode and to the gate electrodes for a long time. Vice versa a comparatively low voltage can be applied to the top and bottom electrodes and to the gate electrodes for a comparatively short time to produce a conducting bridge having a higher resistance. In this way the resistance of the conducting bridge can be influenced by applying high voltages for a long time or low voltages for a short time. The different resistances can be assigned different values so that more than two values can be stored in one memory cell.

Although the preferred embodiment has been described with a pillar or in-via like cell the principle and scope of this aspect of the invention is not limited thereto. Instead any cell type or a mixture between different types like i.e. in-via and mushroom is suitable, which allows to position gate electrodes so that their field can penetrate the volume of switching active material.

Also the number and position of the gate electrodes is not limited to the described embodiment. As described afore any number of gate electrodes suitable for influencing the location of the forming of the conducting bridge is suitable. Preferably and as illustrated in the drawing, the gate electrodes are located at opposite surfaces of the volume of switching active material 1203. Other configurations having a greater number of electrically coupled gate electrodes can be suitable for the exacter location of the location where the conducting bridge will be formed. For example a plurality of electrically coupled gate electrodes being located—like a ring—equidistant and in the direction of the current flow at the same height around the volume of switching material 1203 or one gate electrode formed as a ring around the switching active material can be suitable.

Regarding the wiring and the architecture on a substrate the same principles as described above can be applied here.

As described above the voltage applied to the gate electrode has the same polarity as applied to the top electrode when writing the cell that is when voltages are applied so as to achieve a conducting bridge between the top and bottom electrode. Also when resetting the cell, that is when voltages are applied for erasing or breaking up the conducting bridge, the voltage applied to a gate electrode has the same polarity as the applied to the top electrode. So in a variation of the wiring and topology the gate electrode of a CBRAM cell may be galvanically coupled to the top electrode of the cell.

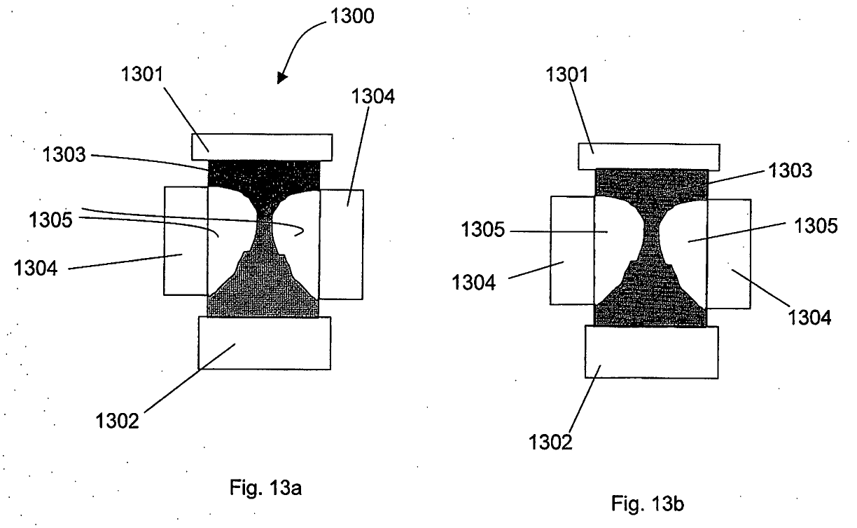

FIGS. 13a, 13b are cross sectional views through schematic conducting bridge memory cells.

Conventional conducting bridge memory cells include a volume of a solid electrolyte being, for example, a semiconducting material as GeS having an Ag doping, which can be homogenous across the entire volume of switching active material or has gradient in the direction from the top or bottom electrode to the opposite.

FIG. 13a illustrates a cross sectional view through a schematic memory cell 1300 having a volume of switching active material 1303 coupled to a top and a bottom electrode 1301, 1302 respectively and gate electrodes 1304.

Upon injecting the doping material, for example Ag, into the semiconductor, for example GeS, a voltage is applied between the top and the bottom electrode. The resulting field affects the Ag to move into the semiconductor.

By applying a gate voltage to the gate electrodes 1304 depletion zones 1305 are generated prohibiting the Ag to move into these, thus affecting a concentration of Ag in the area between the depletion zones 1305. In this way the doping of the GeS with Ag is influenced by the depletion zones that is by applying a gate voltage to the gate electrodes 1304. Consequently by applying a gate voltage to the gate electrodes when “doping” the GeS with Ag the location of the doped area can be influenced so that a conducting path, which will be produced in the area of the high Ag doping, will be generated e.g., in the center of the switching active material or wherever the depletion zones prevented the doping of the semiconductor material.

In this way the GeS or GeSe material can be doped as illustrated in FIG. 13a, i.e. the concentration of Ag sill has a gradient, but in the areas 1305 there is no doping, thus preventing the formation of a conducting bridge in these areas, i.e. in the vicinity of the sidewalls.

FIG. 13b represents a cross sectional view through a schematic memory cell 1300 having top and bottom and gate electrodes 1301, 1302, 1304 and a volume of switching active material 1303 sandwiched in between. In this embodiment a homogenous doping, as indicated by the patterning of the volume 1303 of the switching active material, is desired.

Similarly as described with reference to FIG. 13a, a gate voltage can be applied to the gate electrodes 1304 to affect a concentration of Ag in the centre of the switching active material, i.e. to prevent a concentration at the sidewalls of the cell, when injecting the Ag ions into the GeS material. Thus a conducting bridge will develop in the vicinity of the sidewalls, but—as desired—through the centre of the volume of switching active material. In this way the gate electrodes can be used not only when writing or reading a memory cell but also when doping the material of a conducting bridge cell.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory device comprising at least one resistively switching memory cell, the memory cell comprising:
a volume of switching active material;
a pair of electrodes being galvanically coupled to the volume of switching active material, wherein the pair of electrodes is adapted to send a current through the volume of switching active material; and
at least one gate electrode adapted to cause an electric field penetrating the volume of switching active material.

2. The memory device of claim 1, wherein at least a portion of the electric field is perpendicular to the direction of the current flow.

3. The memory device of claim 1, wherein the electric field influences the location of the current flow.

4. The memory device of claim 1, wherein the pair of electrodes is coupled to the volume of switching active material at opposite surfaces of the switching active material and wherein the gate electrode is located between the electrodes of the pair of electrodes.

5. The memory device of claim 4, wherein the memory cell is one of a pillar type or a in-via type memory cell or a derivative of.

6. The memory device of claim 1, wherein the gate electrode is galvanically insulated against the volume of switching active phase change material.

7. The memory device of claim 6, wherein the insulation between the gate electrode and the switching active material is one of a metal insulating semiconductor contact or a p-n transition or a Schottky-contact.

8. The memory device of claim 1, wherein the gate electrode is galvanically coupled to one electrode of the pair of electrodes.

9. The memory device of claim 1, wherein the memory cell comprises two gate electrodes located on opposite sites of the volume of switching active material.

10. The memory device of claim 9, wherein the gate electrodes are galvanically separated and can be biased individually.

11. The memory device of claim 1, wherein the memory cell comprises one gate electrode surrounding the volume of switching active material.

12. The memory device of claim 11, wherein the gate electrode is formed from the sidewalls of a via in a plate of conducting material.

13. The memory device of claim 1, wherein a plurality of gate electrodes are electrically coupled.

14. A memory device comprising at least one resistively switching memory cell, the memory cell comprising:
a volume of switching active phase change material;
a pair of electrodes being galvanically coupled to the volume of switching active phase change material, wherein the pair of electrodes is adapted to send a current through the volume of switching active phase change material;
a first and a second gate electrode means adapted to cause a first and a second electric field penetrating the volume of switching active material at a first and a second location respectively; and
wherein in the direction of the current flow the second gate electrode means is located downstream of the first gate electrode and the second gate electrode means can be used independently from the first electrode means.

15. The memory device of claim 14, wherein at least a portion of each electric field is perpendicular to the direction of the current flow.

16. The memory device of claim 14, wherein at least one of the gate electrode means comprises at least two gate electrodes being in the direction of the current flow located at the same height.

17. The memory device of claim 16, wherein the at least two gate electrodes of one gate electrode means are located at opposite surfaces of the volume of switching active material.

18. The memory device of claim 14, wherein at least one of the gate electrode means comprises a plurality of gate electrodes being in the direction of the current flow located at the same height and equidistant around the circumference of the volume of the switching active material.

19. The memory device of claim 14, wherein at least one of the gate electrodes surrounds the volume of switching active material.

20. A method for achieving a change in the resistivity of a volume of switching active, phase change material comprising:
sending a heating current pulse through the volume; and
applying at the same time an electric field causing a depletion zone of charge carriers to the volume to define an area of highest current density.

21. The method of claim 20, wherein the electric field is at least partially perpendicular to the direction of the current pulse.

22. The method of claim 20 wherein different electric field strengths are applied to define different sizes of areas of highest current density.

23. The method of claim 20 wherein different electric field strengths are applied to define different locations of areas of highest current density.

24. A method for determining a resistivity value of a volume of switching active, phase change material comprising:
applying a voltage to the volume of switching active material to produce a measurement current; and
applying at the same time an electric field to the volume causing a depletion zone of charge carriers to narrow down an area of highest current density.

25. The method of claim 24, wherein in the process is repeated to determine the size of an area of high resistivity within the volume of switching active material.

26. The method of claim 24, wherein in the process is repeated to determine the location of an area of high resistivity within the volume of switching active material.

27. A method for achieving a change in or for determining a resistivity value of a resistively switching memory cell, the cell comprising:
a volume of switching active material galvanically coupled to a pair of electrodes; and
at least one gate electrode to cause an electric field in the volume of switching active material upon applying a gate voltage to the gate, wherein a gate voltage is applied to the gate electrode to cause an electric field penetrating the volume of switching active material when a voltage is applied to the pair of electrodes for achieving a change in or for determining the resistivity value of the cell.

28. The method of claim 27, wherein the gate voltage is adapted to prevent the switching active material from changing its resistivity in the vicinity of a sidewall of the volume of switching active material.

29. The method of claim 27, wherein the gate voltage applied is adapted so as to develop the area in which the material changes its resistivity is in the center of the volume of switching active material.

30. The method of claim 27 wherein the gate voltage is adapted so as to limit the volume of switching active material wherein the change of resistivity takes place.

31. The method of claim 27, wherein when applying a voltage to the pair of electrodes the gate voltage is controlled to achieve different volume sizes wherein the switching active material changes its resistivity.

32. The method of claim 31, wherein the switching active material is a phase change material.

33. The method of claim 27, the cell furthermore comprising at least a second gate electrode located at the opposite side of the volume of switching active material, and wherein the amplitude of the gate voltage applied to the second gate electrode differs from the amplitude of the gate voltage applied to a first gate electrode.

34. A method for determining a resistivity value of a resistively switching memory cell, the cell comprising:
coupling a volume of switching active material galvanically coupled to a pair of electrodes; and
configuring at least one gate electrode to cause an electric field in the volume of switching active material upon applying a gate voltage to the gate, wherein in subsequent processes different gate voltages are applied to the gate electrode to cause an electric field penetrating the volume of switching active material when applying voltages to the pair of electrodes for determining the resistivity value of the cell.

35. The method of claim 34, wherein the switching active material is phase change material.

36. A method for achieving a change in the resistivity value of a resistively switching memory cell, the cell comprising:
galvanically coupling a volume of switching active material to a pair of electrodes;
at least a first and a second gate electrode means, the second gate electrode means being in the direction of a current flow located downstream from the first gate electrode; and
applying a voltage to one of the first or second gate electrode means to cause an electric field penetrating the volume of switching active material when a voltage is applied to the pair of electrodes.

37. The method of claim 36, wherein the switching active material is phase change material.

38. A method for achieving a change in the resistivity value of a resistively switching memory cell, the cell comprising:
a volume of switching active material galvanically coupled to a pair of electrodes;
at least a first and a second gate electrode means, the second gate electrode means being in the direction of a current flow located downstream from the first gate electrode; and
wherein in subsequent processes a voltage is applied to one of the gate electrode means to cause an electric field penetrating the volume of switching active material when applying a voltage to the pair of electrodes.

39. The method of claim 38, wherein the number of subsequent processes corresponds to the number of gate electrode means.

40. A memory device comprising:
a plurality of resistively switching memory cells, each memory cell comprising a pair of electrodes and at least one gate electrode to cause an electric field penetrating the switching active material, wherein a plurality a pairs of electrodes of memory cells are galvanically coupled to a continuous volume of switching active material, and wherein the volume of switching active material of a cell is a section of the continuous volume of switching active material.

41. The memory device of claim 40, wherein the gate electrodes of adjacent memory cells of adjacent volumes of switching active material are coupled.

42. The memory device of claim 40, wherein the gate electrodes are placed at the sidewalls of a volume of switching active material.

43. The memory device of claim 42, wherein the gate electrodes placed at one sidewall of a volume of switching active material are coupled.

44. The memory device of claim 42, wherein the gate electrodes of adjacent, opposite sidewalls of two volumes of switching active material are coupled.

45. A memory device comprising at least one conductive bridge memory cell, the memory cell comprising:
a volume of switching active material;
a pair of electrodes being galvanically coupled to the volume of switching active material; and
at least one gate electrode adapted to cause an electric field penetrating the volume of switching active material, wherein the gate electrode is galvanically coupled to one of the pair of electrodes.

46. A method for dissolving a conducting path in a volume of conducting path, solid electrolyte material, comprising:
applying a first electric field to the volume, the first electric field directed antiparallel to the direction of a current flow; and
applying a second electric field to the volume, the second electric field directed perpendicular to the first electric field and so as to attract ions to the source of the second electric field.

47. The method of claim 46, wherein the application of the first and second electric field begins and ends at the same time.

48. A method for dissolving the conducting path in a conducting bridge memory cell, the cell comprising:
galvanically coupling a volume of switching active material and a pair of electrodes thereto and at least a gate electrode adapted to cause an electric field penetrating the volume of switching active material; and
applying a gate voltage to the gate electrode when a voltage is applied to the pair of electrodes, the gate voltage causing an electric field so as to attract ions in the switching active material.

49. The method of claim 48, wherein the electric field is perpendicular to a current flowing between the pair of electrodes.

50. The method of claim 48, wherein the voltage applied to the gate electrode is adapted, so that the voltage between one of the pair of electrodes and the gate electrode does not exceed the threshold voltage of creating a conducting path in the switching active material.

51. An array of resistively switching memory cells, each cell comprising:
a volume of switching active material and a pair of electrodes galvanically coupled thereto and at least one gate electrode adapted to cause an electric field penetrating the volume of switching active material, and wherein one of the pair of electrodes is coupled to a bit line or to a ground line by a selection transistor, the other of the pair of electrodes correspondingly coupled to a ground line or a bit line respectively, and wherein the gate of the selection transistor is coupled to a word line and wherein all gate electrodes of the cells are galvanically coupled to a single control line.

52. The array of claim 51, wherein the gate electrodes of all cells are formed by a patterned plate of a conducting material, the patterned plate forming the control line.

53. The array of claim 51, wherein the word lines are parallel to the ground lines and orthogonal to the bit lines.

54. An array of resistively switching memory cells, each cell comprising:
a pair of electrodes galvanically coupled to a volume of switching active material and wherein one of the pair of electrodes is coupled to a bit line or to a ground line by a selection transistor, the other of the pair of electrodes correspondingly coupled to a ground line or a bit line respectively, and wherein the gate of the selection transistor is coupled to a word line, and wherein each cell furthermore comprises at least one gate electrode means adapted to cause an electric field penetrating the volume of switching active material, the gate electrode means coupled to a control line, and wherein the bit lines are parallel to the control lines.

55. The array of claim 54, wherein the bit lines are orthogonal to the word lines.

56. The array of claim 54, wherein the bit lines are orthogonal to the ground lines.

57. The array of claim 54, wherein the cells are arranged in columns of cells and the switching active material is patterned into oblong pieces and wherein the gate electrode means of each cell comprises at least one pair of gate electrodes, the gate electrodes of a column of cells being arranged on opposite sides of one oblong piece of switching active material.

58. The array of claim 57, wherein the gate electrodes at opposing surfaces of two adjacent pieces of switching active material are coupled to one control line.
